(19) United States
(12) Patent Application Publication
(10) Pub. No.: US 2025/0309148 A1
(43) Pub. Date: Oct. 2, 2025

(54) SUBSTRATE WITH COMPONENT EMBEDDED IN A BLIND CAVITY

(71) Applicant: Intel Corporation, Santa Clara, CA (US)

(72) Inventors: Dilan Seneviratne, Phoenix, AZ (US); Sheng Li, Gilbert, AZ (US); Srinivas Venkata Ramanuja Pietambaram, Chandler, AZ (US); Darko Grujicic, Chandler, AZ (US); Numair Ahmed, Chandler, AZ (US); Jieying Kong, Chandler, AZ (US); Whitney Bryks, Tempe, AZ (US); Naiya Soetan-Dodd, Mesa, AZ (US); Cary Kuliasha, Mesa, AZ (US); Shayan Kaviani, Phoenix, AZ (US); Ao Wang, Chandler, AZ (US); Elham Tavakoli, Phoenix, AZ (US); Mahdi Mohammadighaleni, Phoenix, AZ (US); Joseph Peoples, Gilbert, AZ (US); Mohamed R. Saber, College Station, TX (US); Shuren Qu, Gilbert, AZ (US); Vincent Eze, Chandler, AZ (US); Ehsan Zamani, Phoenix, AZ (US)

(73) Assignee: Intel Corporation, Santa Clara, CA (US)

(21) Appl. No.: 18/616,563

(22) Filed: Mar. 26, 2024

(51) Int. Cl. H01L 23/64; H01L 23/538

(52) U.S. Cl. CPC H01L 23/642; H01L 23/5383; H01L 23/5384

(57) ABSTRACT

A microelectronic assembly includes a component embedded into a substrate. The component may include one or more passive components, e.g., for power delivery to one or more components attached to the substrate. The component is embedded into a blind cavity, which extends part-way through the substrate. A metal pad may be included under the component, defining the bottom of the cavity. Alternatively, a polymer material may be included under the component, along the bottom of the cavity. The polymer may provide an even surface for mounting the component and ensure that the component is at the correct height in the substrate.

### BACKGROUND

Integrated circuit (IC) devices receive power from external sources. High performance microelectronic circuits such as processors, graphics, and memory rely on accurate power delivery to function. Power delivery may be achieved by using integrated voltage converters, which typically include on-package or externally mounted passive devices, such as inductors and/or capacitors. For example, a package may include one or more IC dies (e.g., compute dies, memory dies, etc.), along with one or more passive components (e.g., capacitors, inductors, etc.) used to manage power delivery to the IC dies. For example, a compute die and a capacitor die may each be mounted to a surface of a substrate, with electrical connections over the substrate or within the substrate.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of an example substrate with an embedded component over a metal layer, in accordance with various embodiments.

FIG. 2 is a flow diagram of an example process for manufacturing a microelectronic assembly that includes a substrate with an embedded component over a metal layer, in accordance with various embodiments.

FIGS. 3A-3I are cross-sectional views of various stages in an example process for manufacturing the microelectronic assembly with an embedded component over a metal layer, in accordance with various embodiments.

FIG. 4 is a side, cross-sectional view of an example substrate with an embedded component over a polymer layer in a cavity, in accordance with various embodiments.

FIG. 5 is a flow diagram of an example process for manufacturing a microelectronic assembly that includes a substrate with an embedded component over a polymer layer, in accordance with various embodiments.

FIGS. 6A-6H are cross-sectional views of various stages in an example process for manufacturing a microelectronic assembly with an embedded component over a polymer layer, in accordance with various embodiments.

FIG. 7 is a side, cross-sectional view of an example substrate with a component embedded in a cavity using a polymer reset layer, in accordance with various embodiments.

FIG. 8 is a flow diagram of an example process for manufacturing a microelectronic assembly that includes a substrate with an embedded component in a polymer reset layer, in accordance with various embodiments.

FIGS. 9A-9F are cross-sectional views of various stages in an example process for manufacturing a microelectronic assembly with an embedded component in a polymer reset layer, in accordance with various embodiments.

FIG. 10 is a side, cross-sectional view of a substrate with two embedded components with polymer reset layers in cavities of different heights, in accordance with various embodiments.

FIG. 11 is a side, cross-sectional view of a substrate with two embedded components over polymer layers in cavities of different heights, in accordance with various embodiments.

FIG. 12A is a top view of a wafer, and FIG. 12B is a top view of a die that may be included in a microelectronic assembly, in accordance with any of the embodiments disclosed herein.

FIG. 13 is a cross-sectional side view of an IC device that may be included in a microelectronic assembly, in accordance with any of the embodiments disclosed herein.

FIG. 14 is a cross-sectional side view of an IC device assembly that may include a microelectronic assembly, in accordance with any of the embodiments disclosed herein.

FIG. 15 is a block diagram of an example electrical device that may include a microelectronic assembly, in accordance with any of the embodiments disclosed herein.

### DETAILED DESCRIPTION

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

In IC packages, passive devices are used in the power delivery circuitry to power IC devices. In some cases, power regulation circuitry is embedded into a substrate over which one or more dies that include active IC components (e.g., compute dies, memory dies, etc.) are attached. Power into the package may pass through the power regulation circuitry, which delivers desired voltage levels to power the active IC die(s). Embedding the power regulation circuitry (e.g., a passive component, such as a die that includes one or more passive devices) in the package substrate can reduce the surface area of the package (e.g., by not requiring the passive device to be mounted on the surface of the package) and/or increase the amount of computing power and/or memory that can be included in a given package surface area. In addition, embedding the power regulation circuitry can improve power delivery, by reducing the distance between the passive device and the die being powered.

In thin IC packages, an opening may be formed within the package substrate such that the opening extends across the full height of the substrate, or to a metal layer at the back of the substrate. A passive component may have a similar height as the substrate, thus filling the opening through the substrate. Thin IC packages are useful in certain use cases, such as consumer applications where small device size is highly valued. However, for other applications, it is useful to have a thicker IC package, which provides greater mechanical stability, especially at larger surface areas. For example, IC packages for server applications, supercomputers, AI, many-die packages, and other high-demand applications may use relatively thick substrates, e.g., greater than 1 millimeter thick. If the substrate is thicker than the passive component, it can be difficult to form a cavity of the desired height for the embedded passive component.

For example, a substrate may include a number of layers of dielectric material. A cavity for the passive device is formed through a portion of the layers, but does not extend through all of the substrate layers. A cavity that does not extend through the full device is referred to as a blind cavity. Inconsistencies in blind cavities can lead to problems with the substrate. For example, if a blind cavity in a substrate does not have the desired height, the component embedded within the cavity may sit either too low or too high in the cavity. If the blind cavity has an uneven base surface, this may cause the embedded component to be slightly tilted, rather than level. If the passive device is not at the expected position within the substrate, this can reduce mechanical stability for the dies attached over the substrate. Furthermore, if the passive component is not mounted at the correct position within the cavity, it can be challenging to properly align and mount dies over the embedded component.

Various embodiments described herein provide increased stability for the embedded components, and in particular, components embedded into blind cavities in substrates. Managing the positioning of the embedded components improves stability of the dies mounted overtop of the embedded component, e.g., reducing alignment errors. In some embodiments, an embedded component may include one or more passive devices such as inductors, capacitors, or transformers, which can be used in power delivery applications, e.g., to change a voltage level, or to provide power at multiple different voltage levels. As another example, an embedded component may include resistors and/or capacitors, e.g., to reduce electromagnetic interference (EMI) and/or suppress electrostatic discharge (ESD).

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques will exhibit rounded corners, surface roughness, and other features. It is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.” Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner. The term “circuit” means one or more passive and/or active components that are arranged to cooperate with one another to provide a desired function. The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

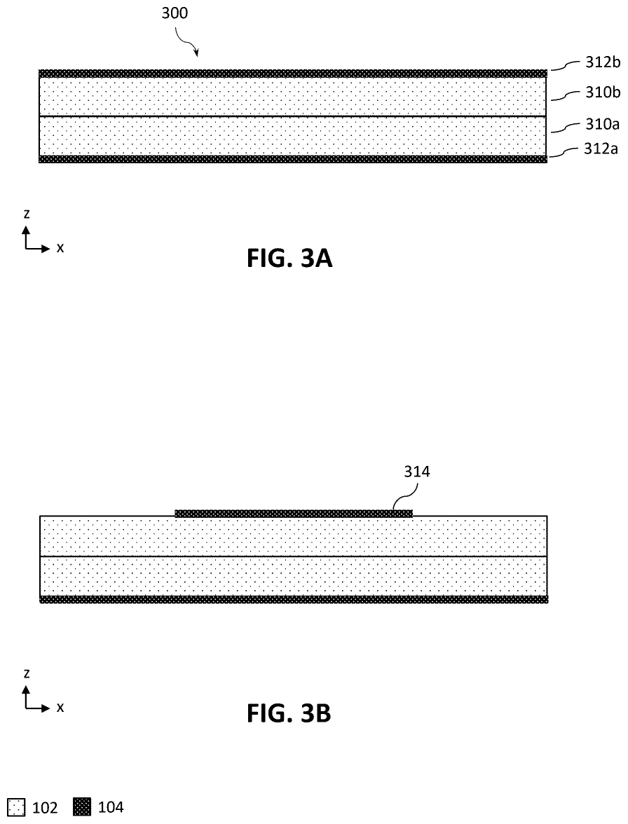

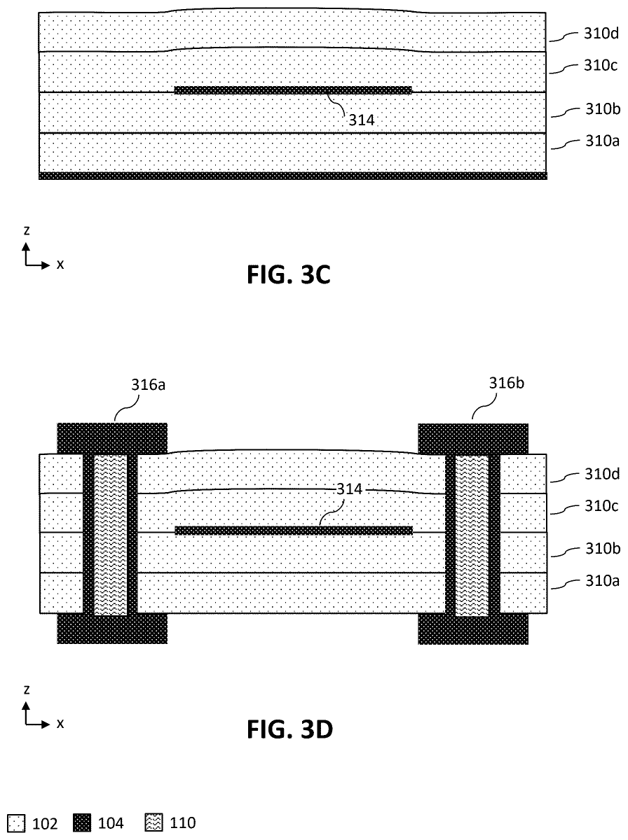

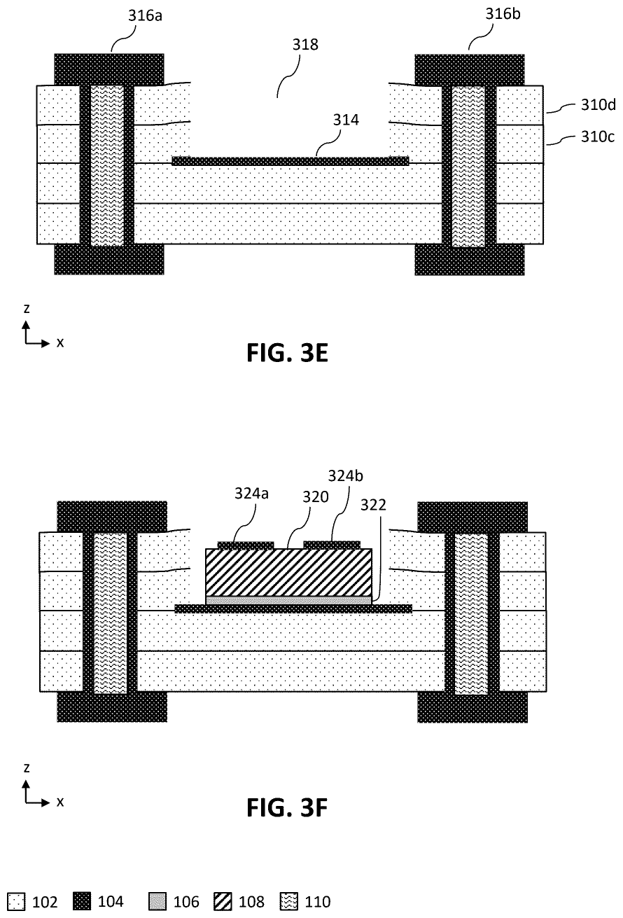

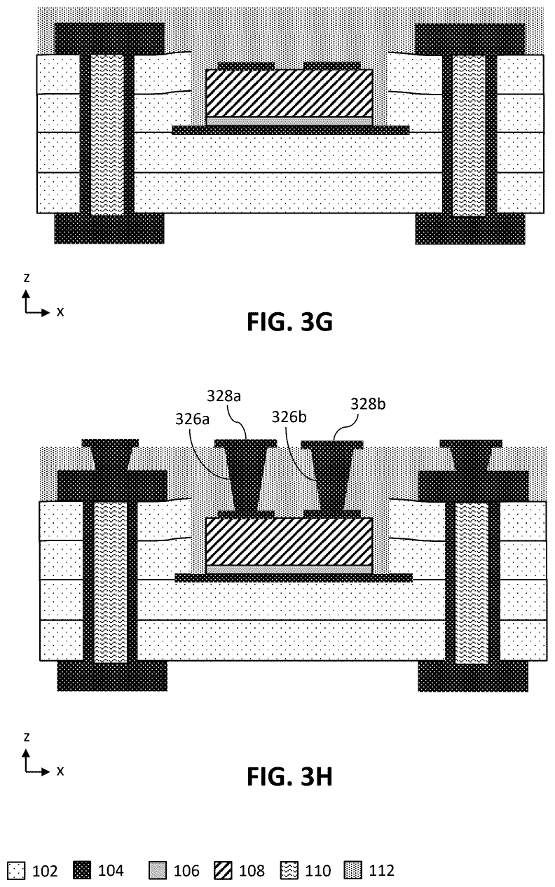

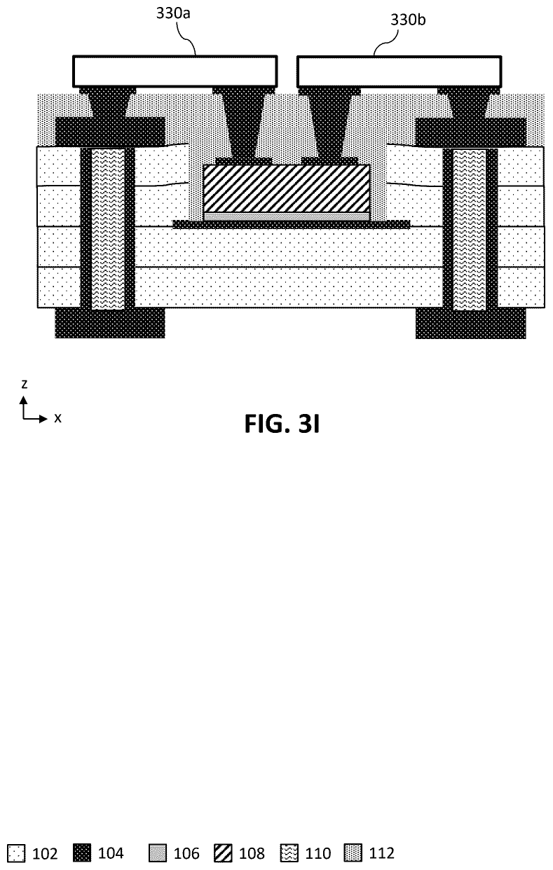

When used to describe a range of dimensions, the phrase “between X and Y” represents a range that includes X and Y. For convenience, the phrase “FIG. 3” may be used to refer to the collection of drawings of FIGS. 3A-3I, etc. Although certain elements may be referred to in the singular herein, such elements may include multiple sub-elements. For example, “an insulating material” may include one or more insulating materials.

Example Substrate with Metal Layer under Embedded Component

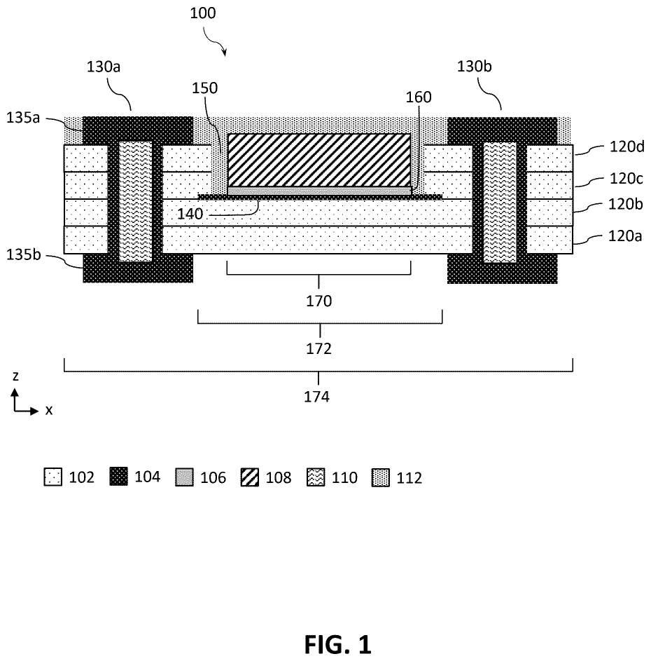

FIG. 1 is a side, cross-sectional view of an example substrate with an embedded component over a metal layer, in accordance with various embodiments. A number of elements referred to in the description of the figures (e.g., FIGS. 1, 3, 4, 6, 7, and 9) with reference numerals are illustrated in these figures with different patterns, with a legend showing the correspondence between the reference numerals and patterns being provided at the bottom of the drawing page. The legend in FIG. 1 illustrates that FIG. 1 uses different patterns to show a first dielectric material 102, a conductive material 104, an adhesive material 106, a component 108, a fill material 110, and a second dielectric material 112.

The substrate 100 includes a bulk dielectric material, here the first dielectric material 102. A cavity 150 is formed within the substrate 100. The component 108 is embedded within the cavity 150. The component 108 may be a die that includes one or more passive devices formed in or over the die, or the component may take a different form, e.g., an individual passive device. One or more dies may be mounted over the substrate 100, e.g., as shown in FIG. 3. The component 108 may include one or more passive components, e.g., an inductor, a capacitor, a transformer, and/or a resistor, not specifically shown in FIG. 1. The component 108 may have a height that is less than a height of the substrate 100. For example, the component 108 may have a height (also referred to as thickness) that is less than 1 millimeter (mm), e.g., between 300 and 600 microns, between 500 and 700 microns, between 600 and 800 microns, or within some other range. The substrate 100 may have a height or thickness of, e.g., 1 mm, 1.2 mm, 1.4 mm, between 1 mm and 1.5 mm, greater than 1.5 mm, or another thickness.

The first dielectric material 102 may be formed as a set of layers, e.g., the four layers 120a, 120b, 120c, and 120d illustrated in FIG. 1. While four layers 120 are illustrated, the first dielectric material 102 may be formed into fewer or more layers, e.g., a single layer, two, or three layers; or five or more layers. In some embodiments, the first dielectric material 102 may include a composite material that includes fibers and a polymer, such as epoxy or resin. The fibers may be pre-impregnated with a resin system, in which case, the first dielectric material 102 may be referred to as a prepreg. In other embodiments, the first dielectric material 102 may include other suitable materials for forming a substrate or core. In various embodiments, the first dielectric material 102 may include a ceramic, an epoxy film having filler particles therein, glass, an organic material, an inorganic material, or combinations of organic and inorganic materials, for example. In some embodiments, the substrate 100 may include layers of the first dielectric material 102 with regions of a conductive material, e.g., the conductive material 104, formed therein, with lines/traces/pads/contacts of the conductive material in one layer electrically coupled to lines/traces/pads/contacts of the conductive material in an adjacent layer by vias extending through the first dielectric material 102.

Plated through-holes 130a and 130b extend through the substrate 100, with contact pads (e.g., contact pads 135a and 135b of the plated through-hole 130a) at their tops and bottoms. The plated through-holes 130 may be formed in openings (e.g., drilled openings) through the substrate 100; the openings are coated with a thin layer of the conductive material 104. The conductive material 104 may be copper or another conductor, e.g., another metal. The conductive material 104 extends through the hole, connecting the contact pads 135 on both sides of the substrate 100. The plated holes are filled in with a fill material 110. The fill material 110 forms a core that provides mechanical support to the plated through-holes 130 and the substrate 100. The fill material 110 may include any suitable dielectric material, e.g., silicon dioxide or glass reinforced epoxy. The plated through-holes 130 facilitate the passage of electrical signals through the substrate 100 and enable the secure attachment of electronic components to the substrate 100.

The cavity 150 is formed in the first dielectric material 102, and the component 108 may be at least partially nested in the cavity 150. In this example, the cavity 150 is formed towards a central region of the substrate 100, between the plated through-holes 130. Within the cavity 150, the component 108 may be surrounded by (e.g., embedded in) another dielectric material, e.g., the second dielectric material 112. In some embodiments, the first dielectric material 102 and the second dielectric material 112 are the same material. In some embodiments, the cavity 150 is tapered, narrowing towards a bottom surface of the cavity 150. The cavity 150 be indicated by a seam between the first dielectric material 102 and the second dielectric material 112. As shown in FIG. 1, in cases where the component 108 is partially nested the cavity 150, a top surface of the component 108 may extend above a top surface of the layer 120d of the first dielectric material 102. In cases where the component 108 is fully nested in the cavity 150, a top surface of the component 108 is co-planar with a top surface of the layer 120d of the first dielectric material 102, or the top surface of the component 108 is below the top surface of the layer 120d of the first dielectric material 102.

The component 108 is over a metal layer 140, also referred to as a metal pad 140 or metal patch 140. The metal layer 140 is formed from the conductive material 104. In some embodiments, the metal layer 140 is copper. In some embodiments, the metal layer 140 may be a different material from the conductive material 104 in the plated through-holes 130. For example, the metal layer 140 may include aluminum, while the plated through-holes 130 include copper. The metal layer 140 defines the bottom surface of the cavity 150. For example, the layers 120c and 120d may be deposited over the metal layer 140, and then portions of the layers 120c and 120d are etched down to the metal layer 140 to form the cavity 150. The cavity 150 may be formed using a laser etch, and the metal layer 140 acts as a laser etch stop. In this example, the component 108 is over the layers 120a and 120b of the substrate 100, and within the layers 120c and 120d of the substrate 100. In other words, the layers 120a and 120b are between a lower side of the substrate 100 (e.g., a lower surface of the layer 120a) and a lower side of the component 108.

The metal layer 140 has an upper side and a lower side (i.e., an upper face and a lower face), and the component 108 (in particular, a lower side of the component 108) is over the upper side of the metal layer 140. The metal layer 140 extends in the x- and y-directions of the coordinate system shown across a greater area than the component 108, such that the full component 108 is over the metal layer 140, i.e., a footprint of the metal layer 140 is greater than a footprint of the component 108. Said another way, the upper side of the metal layer 140 has a surface area that is greater than a surface area of the lower side of the component 108. For example, if the component 108 has a 1 mm by 1 mm footprint, the metal layer 140 has a footprint that is greater than 1 mm×1 mm, e.g., 1.5 mm×1.5 mm. In addition, the metal layer 140 has a footprint that is at least as large (and generally larger than) the footprint of the cavity 150. The metal layer 140 does not extend across the full footprint of the substrate 100; for example, in the cross-section shown, the metal layer 140 does not extend to the plated through-holes 130, and the plated through-holes 130 are positioned away from the metal layer 140. In general, the metal layer 140 is electrically isolated (e.g., by the dielectric material 102) from other conductive structures within the substrate 100.

In the cross-section shown, the component 108 has a width 170, the metal layer 140 has a width 172, and the substrate 100 (including each layer 120 of the substrate 100) has a width 174. The width 172 of the metal layer 140 is greater than the width 170 of the component 108. The width 172 of the metal layer 140 is less than the width 174 of the substrate 100. A same relationship between the sizes of the component 108, metal layer 140, and substrate 100 may be observed in the perpendicular cross-section, i.e., a cross-section in the y-z plane. The metal layer 140 is fully embedded within the substrate 100, e.g., no portion of the metal layer 140 extends to or is visible from an outer face or side of the substrate 100.

The metal layer 140 may have a thickness (measured in the z-direction of the coordinate system shown) that is less than 50 microns, less than 30 microns, less than 20 microns, less than 10 microns, less than 5 microns, between 1 and 10 microns, between 10 and 30 microns, or within some other range of thicknesses.

In this example, a die attach layer 160 is between the component 108 and the metal layer 140. The die attach layer 160 may be a die attach film (DAF). The die attach layer 160 includes the adhesive material 106. In some embodiments, the adhesive material 106 may be an epoxy material, such as an ultraviolet (UV)-curable epoxy (also referred to as a “snap-curable” epoxy) that, upon exposure to UV radiation after deposition, quickly cross-links in place (without requiring a long thermal cure). The use of a UV-curable epoxy as the adhesive material 106 may allow the component 108 to be secured in place quickly so that any shifting of the component 108 that typically occurs during subsequent processing operations may be mitigated or eliminated.

Example Process for Forming Assembly with Metal Pad Under Embedded Component

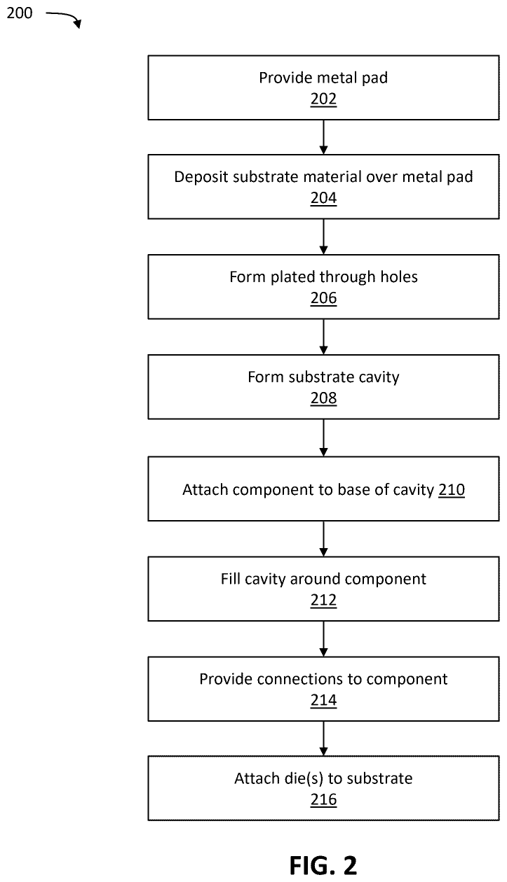

FIG. 2 is a flow diagram of an example process for manufacturing a microelectronic assembly that includes a substrate with an embedded component over a metal layer, in accordance with various embodiments. FIGS. 3A-3I are cross-sectional views of various stages in an example process for manufacturing the microelectronic assembly with an embedded component over a metal layer, in accordance with various embodiments. Although the operations discussed below with reference to FIGS. 2 and 3 (and others of the accompanying drawings representing manufacturing processes) are illustrated in a particular order, these operations may be performed in any suitable order. Further, additional operations which are not illustrated may also be performed without departing from the scope of the present disclosure.

At 202, a metal pad is provided over an initial substrate. FIG. 3A represents a base substrate 300 that may be used to form a substrate with an embedded component over a metal pad. The base substrate 300 includes two layers 310b and 310a of the first dielectric material 102; these layers 310a and 310b may correspond to the layers 120a and 120b of the substrate 100. In other embodiments, the base substrate 300 may have a different number of layers 310, e.g., one layer 310 or three or more layers 310. The base substrate 300 also has a lower metal coating 312a across the bottom side of the base substrate 300 and an upper metal coating 312b across the upper side of the base substrate 300. The metal coatings 312 are formed from the conductive material 104, e.g., copper.

FIG. 3B represents the base substrate 300 with a portion of the upper metal coating 312b removed to form the metal pad 314. For example, a central portion of the upper metal coating 312b is masked, and a subtractive process (e.g., a suitable etching process for the conductive material 104) removes an outer loop of the upper metal coating 312b around the central portion. The central portion of the upper metal coating 312b remains as the metal pad 314. The metal pad 314 corresponds to the metal layer 140 of FIG. 1.

At 204, substrate material is deposited over the metal pad. More generally, the substrate material is deposited over the base substrate after formation of the metal pad. For example, one or more prepreg layers are deposited over the substrate and metal pad, forming layers such as the layers 120c and 120d of FIG. 1.

FIG. 3C illustrates additional substrate layers 310c and 310d formed over the layers 310b and 310a and over the metal pad 314. The layers 310c and 310d correspond to the layers 120c and 120d of FIG. 1. In this example, the layers 310c and 310d include the first dielectric material 102; in other examples, different dielectric materials may be used for different layers, e.g., the layers 310c and 310d may include a different material from the layers 310a and 310b. In other embodiments, a different number of layers may be deposited over the metal pad 314, e.g., one layer or three or more layers.

In some cases, the metal pad 314 may cause the layers over the metal pad 314 to be raised in a region over the metal pad 314. In this example, the layers 310c and 310d have a raised portion or bump over the metal pad 314.

At 206, plated through holes are formed within the substrate. The plated through holes may be formed using standard techniques, e.g., drilling holes through the substrate, coating the holes with a conductor, and filling the holes with a dielectric fill material. FIG. 3D illustrates the substrate after formation of plated through holes 316a and 316b. The plated through holes 316a and 316b are similar to the plated through-holes 130a and 130b.

At 208, a substrate cavity is formed. For example, a laser etching process may be used to remove a portion of the first dielectric material 102 from the substrate. Laser etching uses a focused laser beam to remove material from a specific area of the substrate. The laser etching is performed in a region of the substrate over the metal pad 314, and the metal pad 314 acts as a laser etch stop, preventing etching of the material below the metal pad 314.

FIG. 3E illustrates formation of a cavity 318 within the substrate. The cavity 318 is bounded at the bottom by the metal pad 314. The first dielectric material 102 of the layers 310c and 310d form the side walls of the cavity 318. Thus, the cavity 318 extends though the upper layers of the substrate (here, layers 310d and 310c), but does not extend into the lower layers of the substrate (here, layers 310b and 310a). The cavity 318 is positioned between the plated through holes 316a and 316b.

At 210, a component is attached to the base of the cavity. For example, a DAF or other adhesive layer is used to adhere the base of the component to the base of the cavity. The component may include one or more passive devices, e.g., for power delivery to one or more other dies coupled to the substrate, as described above.

FIG. 3F illustrates the substrate after a component 320 is attached to the base of the cavity 318. The component 320 corresponds to the component 108 of FIG. 1. The component 320 is attached to the base of the cavity 318 and, in particular, to the metal pad 314 by an adhesive layer 322, which corresponds to the die attach layer 160 of FIG. 1. In this example, the component 320 includes two contact pads 324a and 324b, which provide electrical connections to/from the component 320. More or fewer contact pads 324 may be provided in other embodiments. Furthermore, while a single component 320 is illustrated in the cavity 318, in other embodiments, two or more components may be embedded in the cavity 318, e.g., two dies next to each other.

At 212, the portion of the cavity around the component is filled in. Typically, the cavity has a larger footprint than the component, leaving a space around the component. This space can be filled in, e.g., by a dielectric material, to hold the component in place and provide mechanical support for the substrate. The dielectric material, or one or more additional dielectric layers, may also cover a top of the component.

FIG. 3G illustrates the substrate after the second dielectric material 112 has been deposited to fill in the remainder of the cavity 318. The second dielectric material 112 surrounds the sides of the component 320, and in this example, is also deposited over the top of the component and generally over the top of the substrate. While one layer of the second dielectric material 112 is illustrated in FIG. 3, the second dielectric material 112 may be deposited as multiple layers, which may be visible in a cross-section of the device.

At 214, electrical connections to the component are formed over the component. For example, conductive structures are formed within the second dielectric material deposited over the component; at least some of the conductive structures are arranged to contact the contact pads on the embedded component, providing electrical connections to the component.

FIG. 3H illustrates conductive structures (e.g., conductive vias) formed in the second dielectric material 112 to provide electrical connections to the substrate, including to the contact pads 324 of the component 320. In particular, the vias 326a and 326b are coupled to the contact pads 324a and 324b, respectively. Conductive traces 328a and 328b are formed over the vias 326a and 326b, respectively. Vias and traces are also formed over the contact pads of the plated through holes 316a and 316b. While not illustrated in the figures, additional metal layers may be formed. The assembly shown in FIG. 3H is a substrate to which one or more additional dies may be attached, forming an IC package.

At 216, one or more dies are attached to the top of the substrate. For example, one or more dies with active circuit elements (e.g., transistors) are attached to the substrate and electrically coupled to the embedded component. The active dies may be attached over top of the substrate, and electrical connections between the dies and the substrate may be formed, e.g., using solder bonding or direct bonding.

FIG. 3I shows the substrate of FIG. 3H after attaching two dies 330a and 330b to the substrate. In this example, dies 330a and 330b are electrically coupled to the component 320 and also to a respective one of the plated through holes 316. In other embodiments, more or fewer dies 330 may be attached to a substrate having an embedded component over a metal layer.

Example Substrate with Polymer Layer under Embedded Component

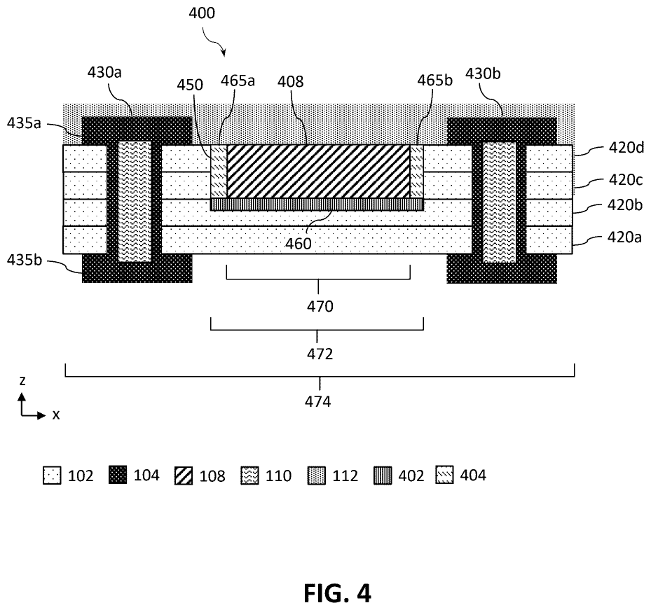

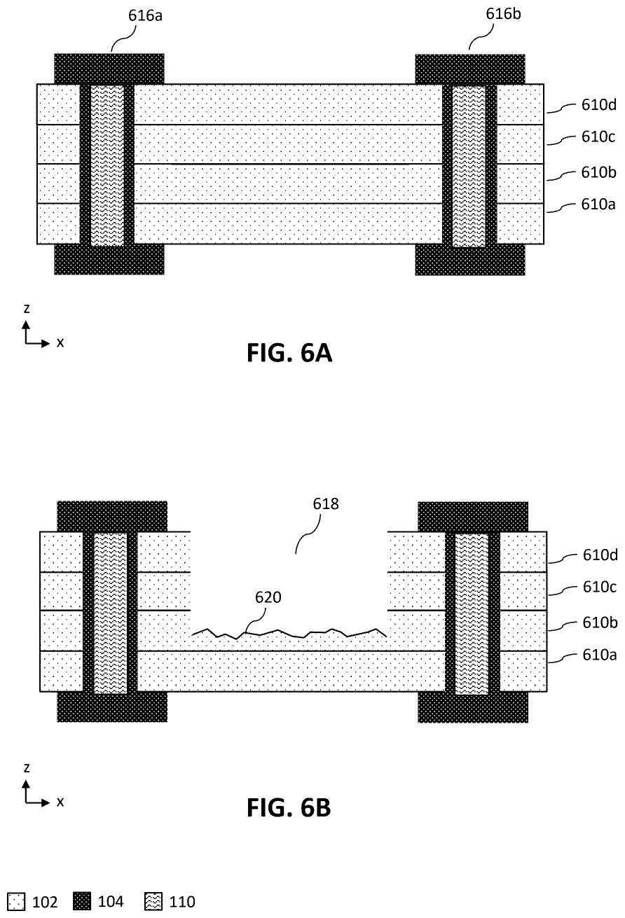

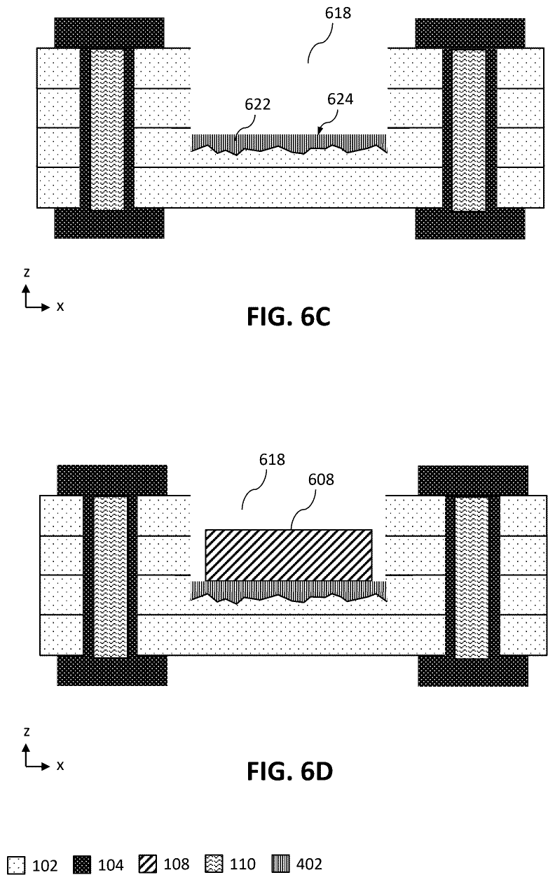

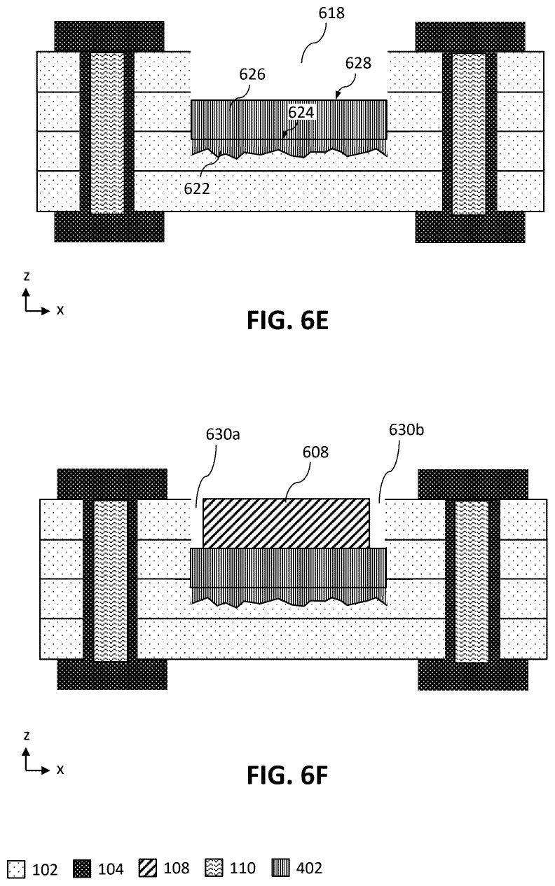

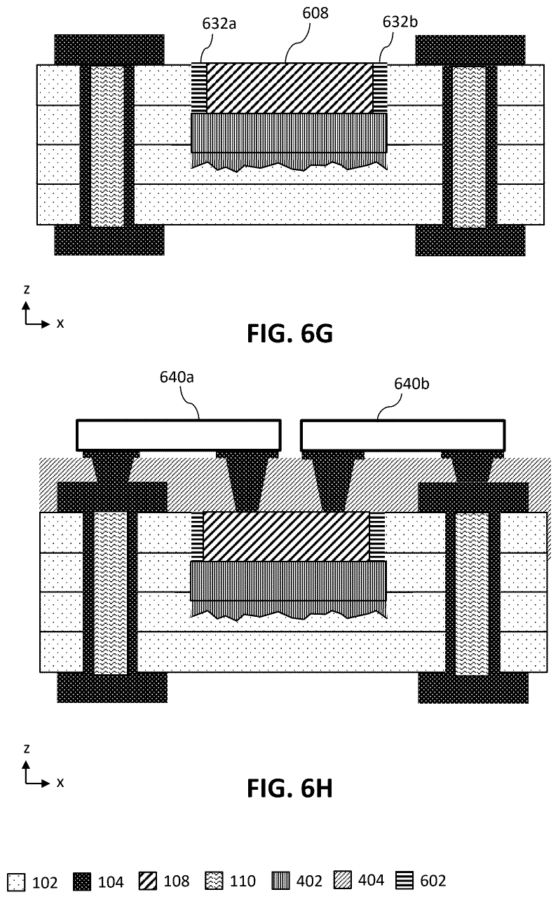

FIG. 4 is a side, cross-sectional view of an example substrate 400 with an embedded component over a polymer layer in a cavity, in accordance with various embodiments. The substrate includes a bulk dielectric material, here the first dielectric material 102. A cavity 450 is formed within the substrate 400, and a component 408 is embedded within the cavity 450. The component 408 may include one or more passive components, e.g., an inductor, a capacitor, a transformer, and/or a resistor, not specifically shown in FIG. 4. The component 408 may be similar to the component 108, and is illustrated in the same pattern as the component 108. One or more additional dies may be mounted over the substrate 400, e.g., as shown in FIG. 6H. As described with respect to FIG. 1, the component 408 may have a height that is less than a height of the substrate 400, e.g., the component 408 is less than 1 mm in thickness, and the substrate 400 is at least 1 mm thick.

The first dielectric material 102 may be formed as a set of layers, e.g., the four layers 420a, 420b, 420c, and 420d illustrated in FIG. 4. While four layers 420 are illustrated, the first dielectric material 102 may be formed into fewer or more layers. The layers 420 are similar to the layers 120 described with respect to FIG. 1.

Plated through-holes 430a and 430b extend through the substrate 400, with contact pads (e.g., contact pads 435a and 435b of the plated through-hole 430a) at their tops and bottoms. The plated through-holes 430 are similar to the plated through holes 130 of FIG. 1.

The cavity 450 is formed in the first dielectric material 102, and the component 408 may be at least partially nested in the cavity 450. In this example, the cavity 450 is formed towards a central region of the substrate 400, between the plated through-holes 430. Within the cavity 450, the component 408 is over a layer 460 of a polymer 402, also referred to as a polymer layer 460 or polymer region 460. The polymer 402 extends across a base of the cavity 450 and fills a lower portion of the cavity 450. For example, the layer 460 may reduce the size and, in particular, a depth of the remaining cavity 450 into which the component 408 is places. In addition, the layer 460 may have a more even upper surface than the surface along the base of the cavity 450.

The polymer layer 460 may have a thickness measured in the z-direction in the coordinate system shown that is, e.g., less than 100 microns, less than 50 microns, less than 25 microns, less than 15 microns, between 5 and 20 microns, between 10 and 50 microns, or within some other range.

In some cases, a thicker layer of the polymer 402 may be deposited, e.g., over 100 microns, or between 100 and 500 microns. While a single layer of the polymer 402 is shown in FIG. 4, in some examples, multiple layers of the polymer 402 may be deposited. For example, the process of etching the cavity 450 may result in a deeper cavity than is desired based on the height of the component 408 and the arrangement of layers over the component 408. In some cases, a thicker polymer layer may be deposited, or multiple layers may be deposited, to achieve the desired cavity depth. An example is illustrated in FIGS. 6E-6H.

The polymer layer 460 is between the lower side of the substrate 400 and the lower side of the component 408. A portion of the substrate 400 (here, the layer 420a and a portion of the layer 420b, which as noted above, may be prepreg layers or another suitable material for forming a substrate) are between the polymer layer 460 and the lower side of the component 408. The lower side of the component 408 is joined to the polymer layer 460. In this example, the lower side of the component 408 is directly coupled or attached to the upper surface of the polymer layer 460. For example, the polymer 402 may be an adhesive polymer, so that the component 408 adheres to the polymer layer 460. In other embodiments, an additional layer, such as the adhesive layer, may be between the polymer layer 460 and the component 408. For example, the die attach layer 160 of FIG. 1 may attach the component 408 to the polymer layer 460.

In some embodiments, the polymer 402 is a self-leveling polymer that produces an even surface along the top side of the layer 460. This results in a level, even surface for placing the component 408. For example, the polymer 402 may be injected into the cavity 450 in a liquid form, e.g., with the polymer 402 suspended in a solvent. The solvent may be evaporated, forming a layer 460 of the polymer 402 with a smooth upper surface. Alternatively, the polymer 402 may be a liquid prior to being cured, and curing process solidifies the polymer 402 after the component 408 has been placed.

As noted above, in some embodiments, the polymer 402 is an adhesive polymer. For example, the polymer 402 may include polyvinyl acetate, an epoxy, and/or an acrylic. In some embodiments, the polymer 402 includes polyurethane and/or polyimide.

In some embodiments, the polymer 402 is a DAF, e.g., an epoxy-based DAF. In such embodiments, multiple layers of the DAF may be deposited to achieve a desired height for the polymer layer 460 and, in turn, for the remainder of the cavity 450.

In some embodiments, multiple types of polymers are combined at the base of the cavity 450. For example, a self-leveling polymer may be deposited and cured, forming a smooth surface. Next, if the remaining portion of the cavity 450 is higher than desired for the component 408, one or more layers of DAF may be placed over the self-leveling polymer to raise the base of the cavity 450, so that the component 408 is at the expected height.

The component 408 may further be surrounded by (e.g., embedded in) another dielectric material, e.g., the surrounding material 404. FIG. 4 illustrates two regions 465a and 465b of the surrounding material 404. If the component 408 is a rectangular prism, the surrounding material 404 may surround the component 408 on four sides. The surrounding material 404 may be the same material as the polymer 402, the same material as the second dielectric material 112, or a material that is different from both the polymer 402 and the second dielectric material 112, e.g., a second polymer material. While the two regions 465a and 465b of the surrounding material 404 are illustrated extending to the upper surface of the component 408, in other embodiments, the surrounding material 404 may extend above the component 408, e.g., the surrounding material 404 may form both the illustrated region 465 and the area of the second dielectric material 112. Alternatively, the surrounding material 404 may extend only partially up the height of the component 408, so that the second dielectric material 112 extends partially into the cavity 450.

The polymer 402 and/or the surrounding material 404 may be selected to be thermally and/or mechanically stable. For example, the polymer 402 and/or surrounding material 404 may have a relatively low coefficient of thermal expansion (CTE), e.g., less than 10 parts per million per° C. (ppm/° C.) over a particular temperature range (e.g., −150° C. to 250° C., −100° C. to 200° C., or some other range of interest). In other examples, the polymer 402 and/or surrounding material 404 may have a CTE of less than 20 ppm/° C., less than 5 ppm/° C., less than 2 ppm/° C., etc. over a particular temperature range.

In some embodiments, the cavity 450 is tapered, narrowing towards a bottom surface of the cavity 450. The side of the cavity 450 be indicated by seams between the polymer 402 and the first dielectric material 102, and seams between the first dielectric material 102 and the surrounding material 404. A top surface of the component 408 may extend above a top surface of the layer 420d of the first dielectric material 102. Alternatively, in cases where the component 408 is fully nested in the cavity 450, a top surface of the component 408 is co-planar with a top surface of the layer 420d of the first dielectric material 102 (as shown in FIG. 4), or the top surface of the component 408 may be below the top surface of the layer 420d of the first dielectric material 102.

In this example, the component 408 is over the layers 420a and 420b of the substrate 400, and within the layers 420c and 420d of the substrate 400. In other words, the layers 420a and 420b are between a lower side of the substrate 400 (e.g., a lower surface of the layer 420a) and a lower side of the component 408. The polymer layer 460 is within the layer 420b of the substrate 400.

The polymer layer 460 extends in the x- and y-directions of the coordinate system shown across a greater area than the component 408, such that the full component 408 is over the polymer layer 460, i.e., a footprint of the polymer layer 460 is greater than a footprint of the component 408. Said another way, the upper side of the polymer layer 460 has a surface area that is greater than a surface area of the lower side of the component 408. For example, if the component 408 has a 1 millimeter (mm) by 1 mm footprint, the polymer layer 460 has a footprint that is greater than 1 mm×1 mm, e.g., 1.5 mm×1.5 mm. In addition, the polymer layer 460 has a footprint that is equal to the footprint of the cavity 450. The polymer layer 460 does not extend across the full footprint of the substrate 400; for example, in the cross-section shown, the polymer layer 460 does not extend to the plated through-holes 430, and the plated through-holes 430 are positioned away from the polymer layer 460.

In the cross-section shown, the component 408 has a width 470, the polymer layer 460 and cavity 450 have a width 472, and the substrate 400 (including each layer 420 of the substrate 400) has a width 474. The width 472 of the polymer layer 460 is greater than the width 470 of the component 408. The width 472 of the polymer layer 460 is less than the width 474 of the substrate 400. The same relationship between the sizes of the component 408, polymer layer 460, and substrate 400 may be observed in the perpendicular cross-section, i.e., a cross-section in the y-z plane. The polymer layer 460 is fully embedded within the substrate 400, e.g., no portion of the polymer layer 460 extends to or is visible from an outer face or side of the substrate 400.

Example Process for Forming Assembly with Polymer Layer Under Embedded Component

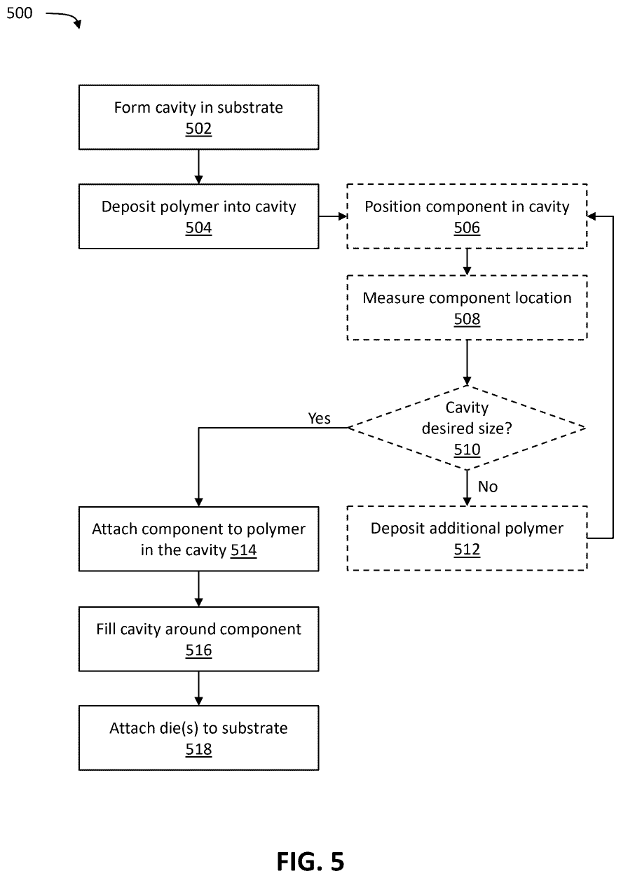

FIG. 5 is a flow diagram of an example process for manufacturing a microelectronic assembly that includes a substrate with an embedded component over a polymer layer, in accordance with various embodiments. FIGS. 6A-6H are cross-sectional views of various stages in an example process for manufacturing a microelectronic assembly with an embedded component over a polymer layer, in accordance with various embodiments. Although the operations discussed below with reference to FIGS. 5 and 6 (and others of the accompanying drawings representing manufacturing processes) are illustrated in a particular order, these operations may be performed in any suitable order. Further, additional operations which are not illustrated may also be performed without departing from the scope of the present disclosure.

At 502, a substrate cavity is formed in a base substrate. For example, drilling or routing may be used to remove a portion of the first dielectric material 102 from the substrate, forming a blind cavity in the base substrate. The drilling or routing is expected to generate a cavity at an expected depth, but as noted above, the bottom surface of the cavity may not be smooth, or there may be some error in the depth achieved.

FIG. 6A illustrates a base substrate with four substrate layers 610a-610d, which correspond to the layers 420a-420d of FIG. 4. In other embodiments, the base substrate may have a different number of layers 610. The base substrate further includes two plated through-holes 616a and 616b, which correspond to the plated through-holes 430 of FIG. 4. The two plated through-holes 616a and 616b may be formed as described with respect to FIG. 1, FIG. 2, and FIG. 3D.

FIG. 6B illustrates formation of a cavity 618 within the substrate. The cavity 618 has a lower surface 620 that is within the layer 610b of the substrate. The first dielectric material 102 of the layers 610b, 610c, and 610d form the side walls of the cavity 618. Thus, the cavity 618 extends though the upper layers of the substrate (here, layers 610d, 610c, and a portion of 610b), but does not extend into the lowest layers of the substrate (here, layers 610a and a portion of 610b). The cavity 618 is positioned between the plated through holes 616a and 616b.

As illustrated in FIG. 6B, the lower surface 620 of the cavity 618 is not even or uniform. The lower surface 620 may have a higher total thickness variation (TTV) than desired, where TTV measures the difference between a maximum and minimum height of the surface 620. Attaching a component directly over the lower surface 620 may produce undesirable results, e.g., the uneven surface may cause the component to sit at an angle relative to the substrate.

At 504, a polymer is deposited into the cavity. Any of the polymer materials described with respect to FIG. 4 may be deposited to coat the lower surface of the cavity. For example, a self-leveling polymer is injected into the cavity. As another example, a DAF is inserted into the cavity. The polymer may be an adhesive polymer with any of the properties described above. The polymer may be deposited as a relatively thin layer, e.g., between 10 and 50 microns.

FIG. 6C illustrates a polymer layer 622 in the cavity 618. The polymer layer 622 includes the polymer 402. The polymer layer 622 extends along a base of the cavity 618 and fills a lower portion of the cavity 618. The polymer layer 622 has a lower surface along the lower surface 620 of the cavity 618, and the polymer layer 622 has an upper surface 624 at a top of the polymer layer 622. The polymer layer 622 effectively raises the base height of the cavity 618, or, said another way, creates a higher surface within the cavity 618 upon which a component can be placed. The polymer layer 622 also forms a smoother surface to attach the component to. In particular, the upper surface 624 of the polymer layer 622 has a lower TTV than the lower surface 620 of the cavity 618, which corresponds to the lower surface of the polymer layer 622. This provides a level surface for attaching a component in the cavity 618.

In some embodiments, a component (e.g., the component 408) is attached to the substrate after formation of the polymer layer 622. For example, if the polymer layer 622 is an adhesive polymer, the component 408 may be directly attached to the polymer layer 622. In such embodiments, the processing method 500 continues to the process 514, described below. In other embodiments, the cavity is measured, and additional material (e.g., one or more additional polymer layers) are deposited in the cavity to achieve the desired height.

For example, to measure the cavity, at 506, a component is positioned in the cavity. FIG. 6D illustrates a component 608 placed in the cavity 618, on top of the polymer layer 622. The component 608 corresponds to the component 408 of FIG. 4. At 508, the location of the component within the cavity is measured, and in particular, a z-height of the upper surface of the component is determined. For example, the location of the upper surface of the component 608 relative to the upper surface of the substrate is measured. At 510, it is determined whether the cavity has the desired size, i.e., whether the upper surface of the component 608 is at the correct position in the z-direction of the coordinate system shown. If the cavity does not have the desired size, at 512, one or more additional layers of polymer are deposited into the cavity. For example, based on the z-height of the top of the component, an additional volume of polymer to deposit is calculated (e.g., a number of layers of DAF, or a volume of a liquid or injectable polymer), and the additional volume is deposited. FIG. 6E illustrates a second layer 626 of the polymer 402 over the polymer layer 622, which may be considered a first layer. The second layer 626 has an upper surface 628 that is above the upper surface 624 of the polymer layer 622.

Different processes may be used for measuring the cavity and/or the component position within the cavity. For example, in some embodiments, the initial cavity (e.g., the cavity shown in FIG. 6C) is measured, and in particular, the depth of the cavity is measured. Due to surface variation across the lower surface 620 of the cavity 618, multiple depth measurements may be obtained. An initial volume of polymer may be calculated based on the measurement, and the volume of polymer is deposited into the cavity 618 to achieve the desired height. In some cases, after the initial polymer layer 622 is deposited, the cavity may be measured (e.g., the depth of the cavity may be measured) without placing the component into the cavity. If the cavity is too deep, additional material (e.g., additional polymer) is then deposited into the cavity to raise the height of the base of the cavity.

At 514, a component is attached to the polymer, which as noted above, forms a higher base level within the cavity. If the polymer filling the lower portion of the cavity is an adhesive polymer, the component can be attached directly to the polymer. The component may include one or more passive devices, e.g., for power delivery to one or more other dies coupled to the substrate, as described above. The polymer may be cured, e.g., by drying or annealing, after attaching the component to the polymer. In other embodiments, a curing process may be performed after additional polymer is deposited in process 516.

FIG. 6F illustrates the substrate after the component 608 is attached to the polymer layer 626. If the processes 506-512 are omitted, or if the initial cavity size after the deposition of the polymer layer 622 was adequate, the component 608 is instead attached to the polymer layer 622.

At 516, the portion of the cavity around the component is filled in. As described with respect to FIGS. 1-3, the cavity has a larger footprint than the component, leaving a space around the component. This space can be filled in by a dielectric material, such as the polymer material below the component or another polymer, to hold the component in place and provide mechanical support for the substrate. As noted above, after the material (e.g., the polymer) surrounding the component is deposited, this material may be cured, e.g., by drying or annealing.

FIG. 6G illustrates the substrate after two regions 632a and 632b of the surrounding material 404 have been deposited to fill in the remainder of the cavity 618. The regions 632a and 632b correspond to the two regions 465a and 465b of FIG. 4. The surrounding material 404 surrounds the sides of the component 608.

At 518 one or more additional dies are attached to the substrate. For example, electrical connections to the component are formed over the component, e.g., within one or more layers of additional dielectric material deposited over the substrate, as described with respect to process 214 of FIG. 2. Furthermore, one or more additional dies are attached to the top of the substrate, as described with respect to process 216 of FIG. 2. FIG. 6H illustrates conductive structures (e.g., conductive vias) formed in the second dielectric material 112 to provide electrical connections to the substrate, including to the component 608, as well as two dies 640a and 640b attached over the substrate. In other embodiments, more or fewer dies 640 may be attached to a substrate having an embedded component over a polymer layer.

Example Substrate with Polymer Layer Under Embedded Component

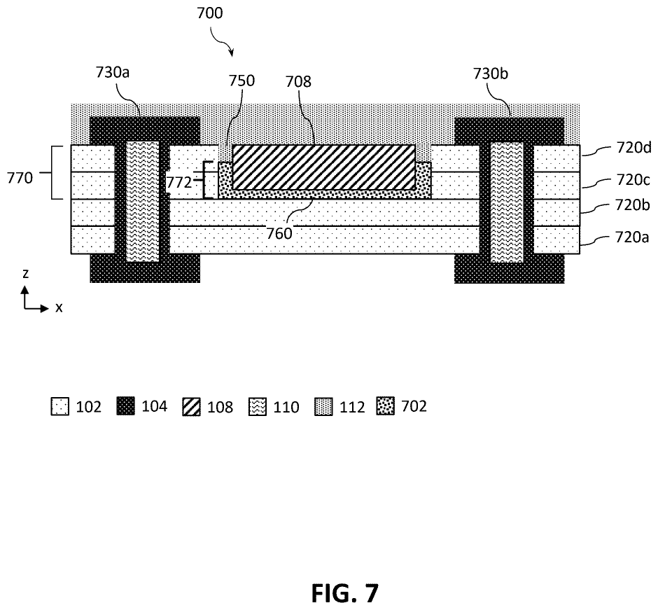

FIG. 7 is a side, cross-sectional view of an example substrate with a component embedded in a cavity using a polymer reset layer, in accordance with various embodiments. The substrate 700 includes a bulk dielectric material, here the first dielectric material 102. A cavity 750 is formed within the substrate 700, and a component 708 is embedded within the cavity 750. The component 708 may include one or more passive components, e.g., an inductor, a capacitor, a transformer, and/or a resistor, not specifically shown in FIG. 7. The component 708 may be similar to the component 108 or 408, and is illustrated in the same pattern as the component 108.

The substrate 700 is generally similar to the substrate 400, except that rather than having a polymer layer 460 with an upper surface, where the component 408 rests on the upper surface, the substrate 700 includes a single polymer region 760 that extends below the component 708 and at least partially around the sides of the component 708. One or more additional dies may be mounted over the substrate 700, e.g., in a similar manner to the dies shown in FIG. 6H. As described with respect to FIG. 1, the component 708 may have a height that is less than a height of the substrate 700, e.g., the component 708 is less than 1 mm in thickness, and the substrate 700 is at least 1 mm thick.

The first dielectric material 102 may be formed as a set of layers, e.g., the four layers 720a, 720b, 720c, and 720d illustrated in FIG. 7. While four layers 720 are illustrated, the first dielectric material 102 may be formed into fewer or more layers. The layers 720 are similar to the layers 120 described with respect to FIG. 1.

Plated through-holes 730a and 730b extend through the substrate 700, with contact pads at their tops and bottoms. The plated through-holes 730 are similar to the plated through holes 130 of FIG. 1.

The cavity 750 is formed in the first dielectric material 102, and the component 708 may be at least partially nested in the cavity 750. In this example, the cavity 750 is formed towards a central region of the substrate 700, between the plated through-holes 730. The polymer region 760 extends along the base of the cavity 750 and at least partway up the sides of the cavity 750, and the component 708 is over the polymer region 760 and at least partly surrounded on its sides by the polymer region 760. The polymer region 760 is formed from a polymer 702, which may include any of the materials described with respect to the polymer 402, e.g., polyvinyl acetate, an epoxy, an acrylic, polyurethane, and/or polyimide. The polymer 702, upon deposition, may have a viscous texture that can be deformed by the component 708 but does not allow the component 708 to sink to the bottom of the cavity 750 prior to curing of the polymer 702. In addition, the polymer 702 may be adhesive, so that the component 708 adheres to the polymer 702. The polymer 702 may be selected to be thermally and/or mechanically stable, as described with respect to FIG. 4.

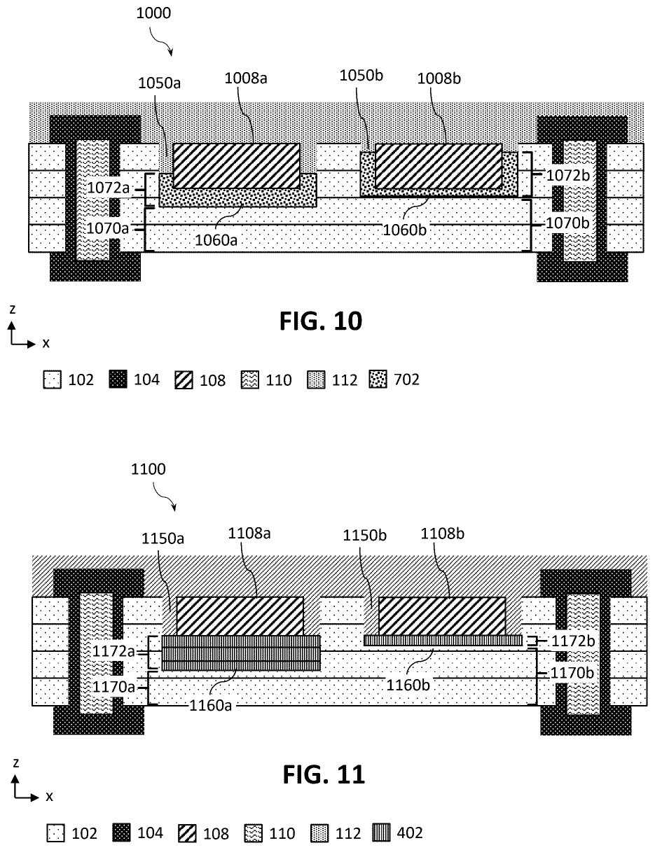

The polymer region 760 has a lower portion that extends across a base of the cavity 750 and fills a corresponding lower portion of the cavity 750. The polymer region 760 also has side portions between the sides of the component 708 and the sidewalls of the cavity 750. The side portions of the polymer region 760 provide stability for the component 708 within the cavity 750. The lower portion of the polymer region 760 has a thickness that is based on the initial height of the cavity 750 and the depth of the component 708. The side portions of the polymer region 760 have a height that depends on the amount of the polymer 702 displaced by setting the component 708 into the cavity 750 and into the polymer 702. An example illustrating two cavities with different heights, and their effects on the geometry of the polymer region 760, is shown in FIG. 10.

The polymer region 760 (and in particular, the lower portion of the polymer region 760) is between the lower side of the substrate 700 and the lower side of the component 708. A portion of the substrate 700 (here, the layers 720a and 720b, which as noted above, may be prepreg layers or another suitable material for forming a substrate) are between the polymer region 760 and the lower side of the component 708. The lower side of the component 708 and the sides of the component 708 are joined to the polymer region 760.

The component 708 may further be surrounded by (e.g., embedded in) another dielectric material, e.g., the second dielectric material 112. FIG. 7 illustrates that an upper portion of the component 708 is surrounded on its sides by the second dielectric material 112, which also extends over the component 708 and, more generally, over the substrate 700. In some embodiments, including the embodiment shown in FIG. 7, the cavity 750 has a height 770 that is greater than a height 772 of the side portions of the polymer region 760. In other embodiments, the polymer region 760 may be as tall as the cavity 750, so that the second dielectric material 112 does not extend into the cavity 750.

In some embodiments, the cavity 750 is tapered, narrowing towards a bottom surface of the cavity 750. The side of the cavity 750 be indicated by seams between the polymer 702 and the first dielectric material 102, and, near the upper portion of the component 708, at seams between the first dielectric material 102 and the second dielectric material 112. A top surface of the component 708 may extend above a top surface of the layer 720d of the first dielectric material 102. Alternatively, in cases where the component 708 is fully nested in the cavity 750, a top surface of the component 708 is co-planar with a top surface of the layer 720d of the first dielectric material 102 (as shown in FIG. 7), or the top surface of the component 708 may be below the top surface of the layer 720d of the first dielectric material 102.

In this example, the component 708 is over the layers 720a and 720b of the substrate 700, and within the layers 720c and 720d of the substrate 700. In other words, the layers 720a and 720b are between a lower side of the substrate 700 (e.g., a lower surface of the layer 720a) and a lower side of the component 708. The polymer region 760 is within the layers 720c and 720d of the substrate 700.

The relative widths and footprints of the component 708, cavity 750, polymer region 760, and substrate 700 correspond to those described with respect to the component 408, cavity 450, polymer layer 460, and substrate 400 described with respect to FIG. 4. The polymer region 760 is fully embedded within the substrate 700, e.g., no portion of the polymer region 760 extends to or is visible from an outer face or side of the substrate 700.

Example Process for Forming Assembly with Polymer Reset Layer and Embedded Component

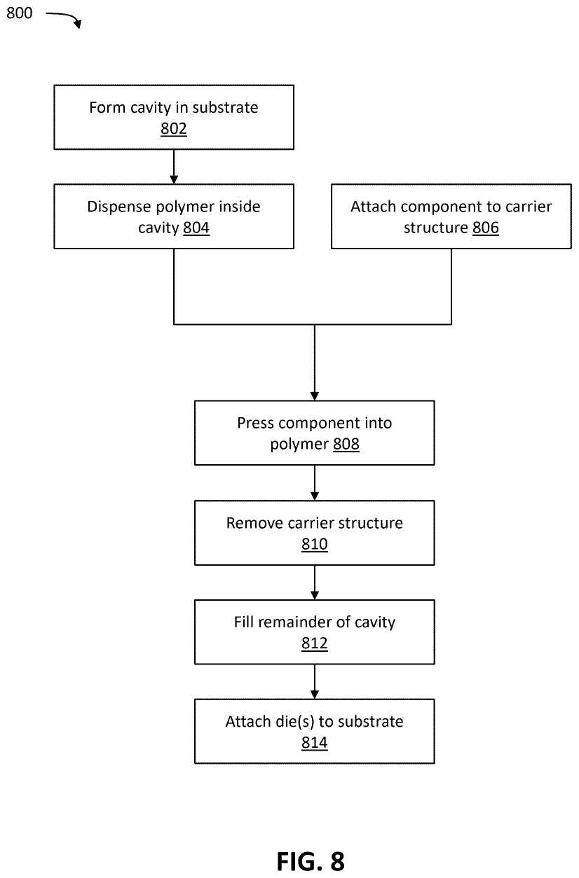

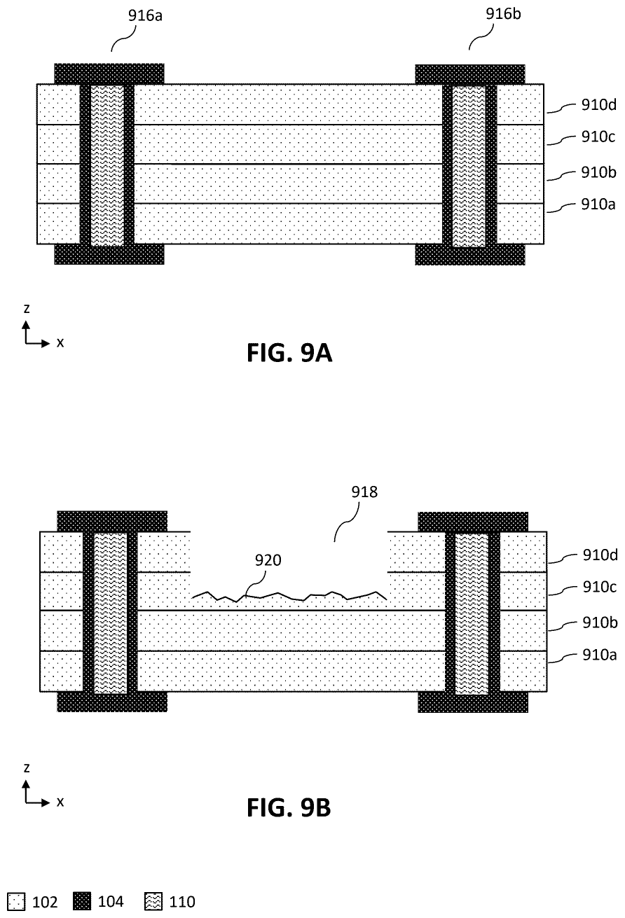

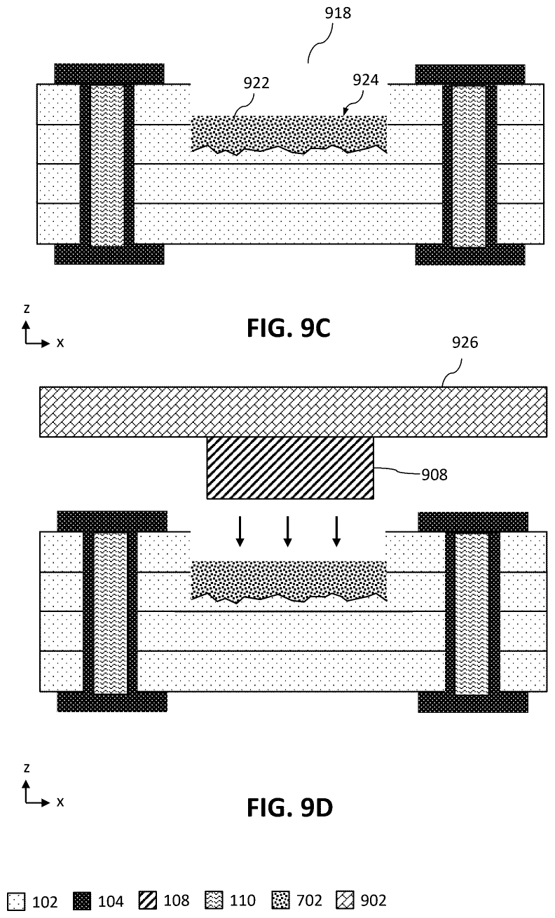

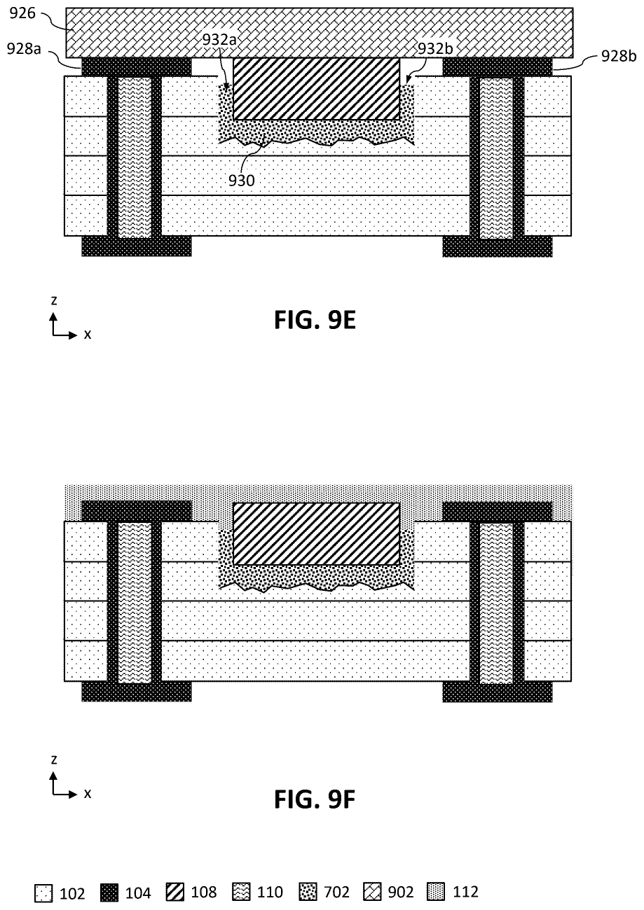

FIG. 8 is a flow diagram of an example process for manufacturing a microelectronic assembly that includes a substrate with an embedded component in a polymer reset layer, in accordance with various embodiments. FIGS. 9A-9F are cross-sectional views of various stages in an example process for manufacturing a microelectronic assembly with an embedded component in a polymer reset layer, in accordance with various embodiments. Although the operations discussed below with reference to FIGS. 8 and 9 (and others of the accompanying drawings representing manufacturing processes) are illustrated in a particular order, these operations may be performed in any suitable order. Further, additional operations which are not illustrated may also be performed without departing from the scope of the present disclosure.

At 802, a substrate cavity is formed in a base substrate. For example, a mechanical drilling may be used to remove a portion of the first dielectric material 102 from the substrate. The mechanical drilling forms a blind cavity in the base substrate. The drilling is expected to generate a cavity at an expected depth, but as noted above, the bottom surface of the cavity may not be smooth, or there may be some error in the depth achieved.

FIG. 9A illustrates a base substrate with four substrate layers 910a-910d, which correspond to the layers 720a-720d of FIG. 7. In other embodiments, the base substrate may have a different number of layers 910. The base substrate further includes two plated through-holes 916a and 916b, which correspond to the plated through-holes 730 of FIG. 7. The plated through-holes 916 may be formed as described with respect to FIG. 1, FIG. 2, and FIG. 3D.

FIG. 9B illustrates formation of a cavity 918 within the substrate. The cavity 918 has a lower surface 920 that is within the layer 910c of the substrate. The first dielectric material 102 of the layers 910c and 910d form the side walls of the cavity 918. Thus, the cavity 918 extends though the upper layers of the substrate (here, layers 910d and 910c), but does not extend into the lowest layers of the substrate (here, layers 910a and 910b). The cavity 918 is positioned between the plated through holes 916a and 916b.

As illustrated in FIG. 9B, the lower surface 920 of the cavity 918 is not even or uniform. The lower surface 920 may have a higher total thickness variation (TTV) than desired, where TTV measures the difference between a maximum and minimum height of the surface 920. Attaching a component directly over the lower surface 920 may produce undesirable results, e.g., the uneven surface may cause the component to sit at an angle relative to the substrate.

At 804, a polymer is deposited into the cavity. Any of the polymer materials described with respect to FIG. 7 may be deposited into the cavity. For example, a viscous, adhesive polymer is injected into the cavity. In some embodiments, the volume of the cavity is measured prior to injecting the polymer, as described with respect to FIG. 5. The volume of polymer to deposit may be calculated based on the measured volume of the cavity, so that the polymer is a large enough volume to put a component at a desired height.

FIG. 9C illustrates a polymer region 922 in the cavity 918. The polymer region 922 includes the polymer 702. The polymer region 922 extends along a base of the cavity 918 and fills a lower portion of the cavity 918. The polymer region 922 has a lower surface along the lower surface 920 of the cavity 918, and the polymer region 922 has an upper surface 924 at a top of the polymer region 922.

At 806, a component is attached to a carrier structure, such as a carrier wafer, plate, or panel. The top surface of the component, i.e., the side intended to be accessed from the top of the finished substrate, is attached to the carrier structure. The carrier structure may be any suitable support structure that can temporarily adhere to the component, and then be removed from the component. Process 806 is illustrated in parallel with processes 802 and 804, but may be performed before or after processes 802 and 804 (typically before).

At 808, the component is pressed into the polymer in the cavity, while attached to the carrier structure. The z-position of the component in the cavity is determined by the carrier structure, which is held at a certain level by the regions of the substrate around the cavity, e.g., the upper contact pads of the plated through-holes. The component deforms the polymer so that it partially encloses the component, e.g., so that it surrounds or encases a lower portion of the component.

FIG. 9D illustrates a component 908 attached to a carrier structure 926. The component 908 is being moved towards the substrate and into the cavity, as indicated by the arrows. FIG. 9E shows the component 908 after being placed into the cavity 918. In this example, the carrier structure 926 is pushed onto the upper contact pads 928a and 928b of the plated through holes. In general, the carrier structure 926 is pushed onto the highest structure on the substrate, and the component 908 that is attached to the carrier structure 926 is pushed into the cavity. If it is desired for the upper side of the component 908 to be below the upper structure of the substrate (e.g., the upper contact pads 928a and 928b in this example), an additional layer may be placed between the carrier structure 926 and the component 908 during transfer of the component 908 into the substrate.

When the carrier structure 926 presses the component 908 into the cavity, a portion of the polymer 702 is displaced. In particular, an upper portion of the initial polymer region 922 is pushed up around the sides of the component 908, forming a deformed polymer region 930 that includes two side portions 932a and 932b, as well as a portion below the 908. After deforming the polymer region, an upper surface of the polymer region 930 under the component 908 is smooth, e.g., with a lower TTV than the lower surface 920 of the cavity 918.

At 810, the carrier structure is removed from the component. At 812, a remainder of the cavity is filled in with a dielectric material. For example, a layer of buildup film is deposited over the substrate, filling in unfilled portions of the cavity. In some embodiments, prior to filling in the rest of the cavity, the polymer may be cured, e.g., by drying or annealing.

FIG. 9F illustrates the substrate after the second dielectric material 112 is deposited, filling in the remainder of the cavity and forming a dielectric layer over the component 908.

At 814, one or more additional dies are attached to the substrate. For example, electrical connections to the component are formed over the component, e.g., within the second dielectric material 112 over the component 908, as described with respect to process 214 of FIG. 2. Furthermore, one or more additional dies are attached to the top of the substrate, as described with respect to process 216 of FIG. 2. The dies over the component 908 and electrical connections may be similar to the dies 640 and electrical connections shown in FIG. 6H.

Example Substrates with Multiple Embedded Components

The use of the techniques for embedding components described herein may, in some instances, be observed by comparing multiple embedded components, and the cavities surrounding the embedded components. For example, the techniques may be observed in a single package that includes multiple embedded components, or by comparing two or more packages that each include an embedded component. FIGS. 10 and 11 illustrate two examples of substrates with multiple embedded components, where the use of certain ones of the polymer layers described herein may result in different cavity geometries.

FIG. 10 is a side, cross-sectional view of a substrate with two embedded components with polymer reset layers in cavities of different heights, in accordance with various embodiments. FIG. 10 illustrates a substrate 1000 with two embedded components 1008a and 1008b. The components 1008a and 1008b are each embedded in a respective cavity 1050a or 1050a, and each component 1008a and 1008b is embedded into a polymer region 1060a or 1060b, which is similar to the polymer region 760 described with respect to FIG. 7.

In this example, the cavity 1050a is larger than the cavity 1050b, e.g., due to inconsistency when drilling the cavities 1050. In particular, the depth of the cavity 1050a, i.e., the distance that the cavity 1050a extends into the substrate 1000, is greater than the depth of the cavity 1050b. A height 1070a of the substrate 1000 (e.g., the height of the first dielectric material 102) between the base of the substrate 1000 and the base of the cavity 1050a is less than the height 1070b of the substrate 1000 (e.g., the height of the first dielectric material 102) between the base of the substrate 1000 and the base of the cavity 1050b. When placing the components 1008, a greater volume of the polymer 702 in the cavity 1050b is displaced than the volume of the polymer 702 in the cavity 1050a is displaced. This results in the polymer region 1060b having a greater height 1072b than a height 1072a of the polymer region 1060a.

While the components 1008a and 1008b are illustrated as being embedded in two cavities 1050a and 1050b in a single substrate 1000, in other embodiments, the cavities 1050a and 1050c and components 1008a and 1008b are within two different substrates. Thus, the polymer regions 1060a and 1060b and cavities 1050a and 1050b with differing geometries may be observed across multiple different devices produced using the process described with respect to FIGS. 8 and 9.

FIG. 11 is a side, cross-sectional view of a substrate with two embedded components over polymer layers in cavities of different heights, in accordance with various embodiments. FIG. 1 illustrates a substrate 1100 with two embedded components 1108a and 1108b. The components 1108a and 1108b are each embedded in a respective cavity 1150a or 1150a, and each component 1108a and 1108b is over a respective polymer region 1160a or 1160b, which is similar to the polymer layer 460 described with respect to FIG. 4.

In this example, the cavity 1150a is larger than the cavity 1150b, e.g., due to inconsistency when drilling the cavities 1150. In particular, the depth of the cavity 1150a, i.e., the distance that the cavity 1150a extends into the substrate 1100, is greater than the depth of the cavity 1150b. A height 1170a of the substrate 1100 (e.g., the height of the first dielectric material 102) between the base of the substrate 1100 and the base of the cavity 1150a is less than the height 1170b of the substrate 1100 (e.g., the height of the first dielectric material 102) between the base of the substrate 1100 and the base of the cavity 1150b. Prior to placing the components 1108, a greater volume of the polymer 402 is deposited into the cavity 1150a than into the cavity 1150b. For example, three layers of the polymer 402 are deposited into the cavity 1150a, to raise the base of the cavity 1150a for placing the component 1108a. This results in the polymer region 1160a having a greater height 1172a than a height 1172b of the polymer region 1160b.

While the components 1108a and 1108b are illustrated as being embedded in two cavities 1150a and 1150b in a single substrate 1100, in other embodiments, the cavities 1150a and 1150c and components 1108a and 1108b are within two different substrates. Thus, the polymer regions 1160a and 1160b and cavities 1150a and 1150b with differing geometries may be observed across multiple different devices produced using the process described with respect to FIGS. 5 and 6.

### Example Devices

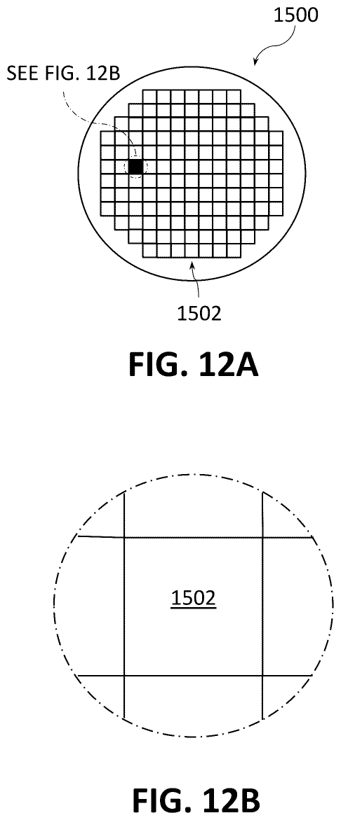

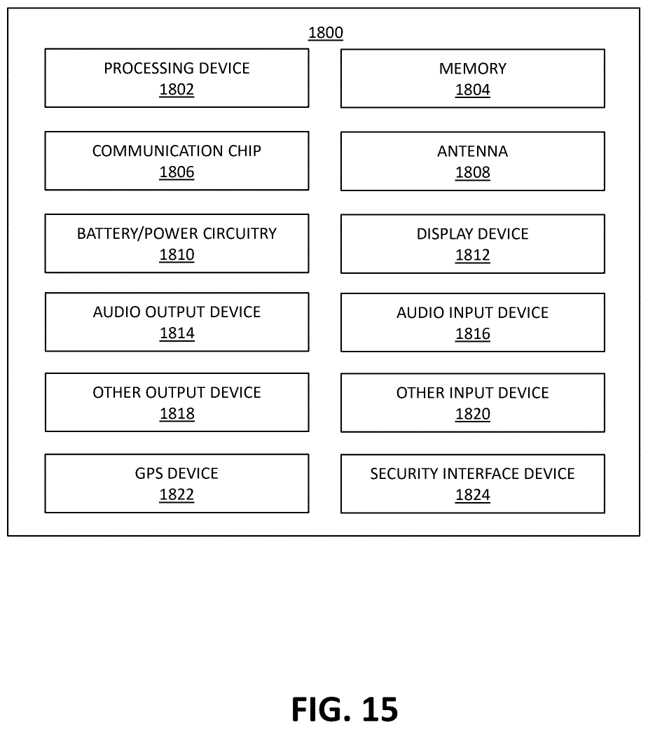

The microelectronic assemblies disclosed herein may be included in any suitable electronic component. FIGS. 12-15 illustrate various examples of apparatuses that may include, or be included in, any of the microelectronic assemblies disclosed herein.

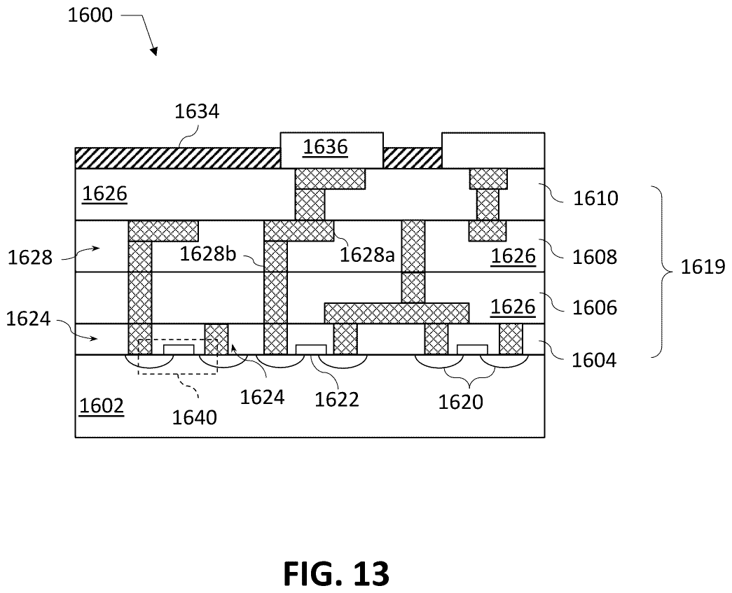

FIGS. 12A and 12B is a top view of a wafer 1500 (FIG. 12A) and a die 1502 (FIG. 12B) that may be included in any of the microelectronic assemblies disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies disclosed herein. The die 1502 may include one or more transistors (e.g., some of the transistors 1640 of FIG. 13, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 12) or other logic that is configured to store information in the memory devices or execute instructions stored in the memory array. In some embodiments, a die 1502 may be a central processing unit, a radio frequency chip, a power converter, or a network processor. Various ones of the microelectronic assemblies disclosed herein may be manufactured using a die-to-wafer assembly technique in which some dies are attached to a wafer 1500 that include others of the dies, and the wafer 1500 is subsequently singulated.

FIG. 13 is a cross-sectional side view of an IC device 1600 that may be included in any of the microelectronic assemblies disclosed herein. One or more of the IC devices 1600 may be included in one or more dies 1502 (FIG. 12B). The IC device 1600 may be formed on a die substrate 1602 (e.g., the wafer 1500 of FIG. 12A) and may be included in a die (e.g., the die 1502 of FIG. 12B). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 12B) or a wafer (e.g., the wafer 1500 of FIG. 12A).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 13 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a PMOS or a NMOS transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 13 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 13. Although a particular number of interconnect layers 1606-1610 is depicted in FIG. 13, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 13. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 9. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 9, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die, the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die, the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

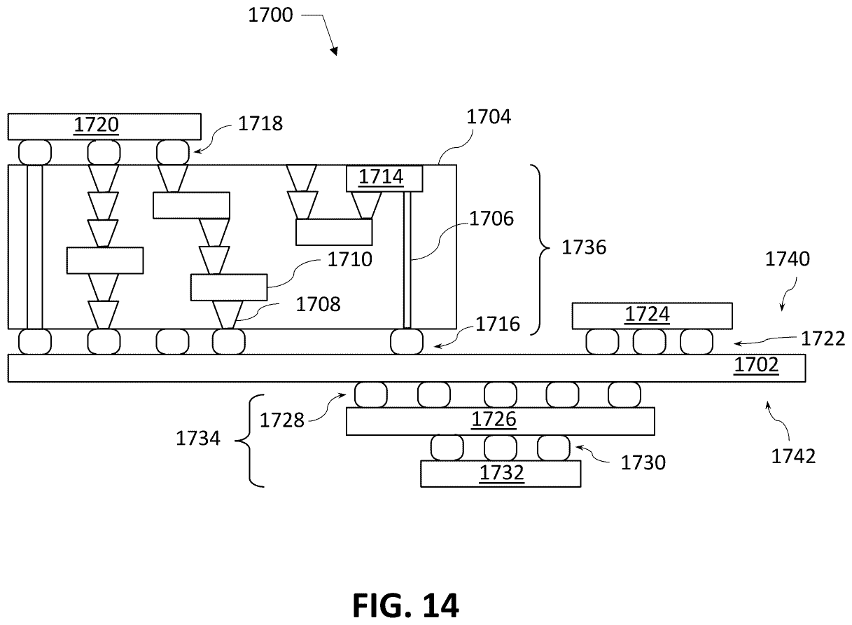

FIG. 14 is a cross-sectional side view of an IC device assembly 1700 that may include any of the microelectronic assemblies disclosed herein. In some embodiments, the IC device assembly 1700 may be a microelectronic assembly. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 14 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 14), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 14, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 12B), an IC device (e.g., the IC device 1600 of FIG. 9), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 14, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 14 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 12 is a block diagram of an example electrical device 1800 that may include one or more of the microelectronic assemblies disclosed herein. For example, any suitable ones of the components of the electrical device 1800 may include one or more of the IC device assemblies 1700, IC devices 1600, or dies 1502 disclosed herein, and may be arranged in any of the microelectronic assemblies disclosed herein. A number of components are illustrated in FIG. 12 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 12, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

### Select Examples

The following paragraphs provide various examples of the embodiments disclosed herein.

Example 1 provides an assembly including a substrate having a first side and a second side opposite the first side; a component at least partially embedded in the substrate, the component having a first side and a second side opposite the first side, where the first side of the component is above the first side of the substrate; and a metal layer in the substrate, the metal layer between the first side of the substrate and the first side of the component.

Example 2 provides the assembly of example 1, where the component includes a passive device.

Example 3 provides the assembly of example 2, where the passive device is a capacitor.

Example 4 provides the assembly of any of examples 1-3, where the metal layer includes copper.

Example 5 provides the assembly of any of examples 1-4, where the metal layer has a thickness of less than 50 microns.

Example 6 provides the assembly of any of examples 1-5, where the first side of the component has a first surface area, and a side of the metal layer has a second surface area that is greater than the first surface area.

Example 7 provides the assembly of any of examples 1-6, where the metal layer is fully embedded in the substrate.

Example 8 provides the assembly of any of examples 1-7, where the substrate includes a plurality of dielectric layers, where at least a first dielectric layer is between the first side of the substrate and the first side of the component.

Example 9 provides the assembly of example 8, where a second dielectric layer of the plurality of dielectric layers is in a same layer as the component.

Example 10 provides the assembly of any of examples 1-9, where the metal layer is electrically isolated from the component.

Example 11 provides the assembly of any of examples 1-10, further including a through hole extending through the substrate, the through hole positioned away from the metal layer.

Example 12 provides a substrate including a first layer including a dielectric material, the first layer having a first width; a second layer including the dielectric material; a metal pad between the first layer and the second layer, the metal pad having a second width less than the first width; and a passive device in the second layer and over the metal pad.

Example 13 provides the substrate of example 12, where the passive device is a capacitor.

Example 14 provides the substrate of example 12 or 13, where the metal pad includes copper.

Example 15 provides the substrate of any of examples 12-14, where the metal pad has a thickness of less than 50 microns.

Example 16 provides the substrate of any of examples 12-14, where the metal pad has a thickness of less than 20 microns.

Example 17 provides the substrate of any of examples 12-16, where the metal pad is electrically isolated from the passive device.

Example 18 provides the substrate of any of examples 12-17, further including an adhesive layer between the metal pad and the passive device.

Example 19 provides a method including providing a metal layer over a first dielectric layer, the metal layer having an upper surface having a first surface area less than a second surface area of the first dielectric layer; depositing a second dielectric layer over the metal layer and the first dielectric layer; forming a cavity within the second dielectric layer, the cavity extending to the metal layer; and placing a passive device within the cavity.

Example 20 provides the method of example 19, where the metal layer has a first width and the cavity has a second width that is less than the first width.

Example 21 provides an assembly including a substrate having a first side and a second side opposite the first side; a component at least partially embedded in the substrate, the component having a first side between the first side of the substrate and the second side of the substrate; and a polymer region embedded in the substrate, the polymer region between the first side of the substrate and the first side of the component.

Example 22 provides the assembly of example 21, where the polymer region is joined to the first side of the component.

Example 23 provides the assembly of example 21 or 22, where the component is within a cavity of the substrate, the cavity having a greater width than the component.

Example 24 provides the assembly of example 23, where the polymer region extends across a base of the cavity.

Example 25 provides the assembly of example 24, where the polymer region has a greater width than the component, and the polymer region has a same width as the cavity.

Example 26 provides the assembly of any of examples 21-25, where the component includes a passive device.

Example 27 provides the assembly of example 26, where the passive device is a capacitor.

Example 28 provides the assembly of any of examples 21-27, where the substrate includes a plurality of dielectric layers, where at least a first dielectric layer is between the first side of the substrate and the polymer region.

Example 29 provides the assembly of example 28, where a second dielectric layer of the plurality of dielectric layers is in a same layer as the component.

Example 30 provides the assembly of any of examples 21-29, where a first surface of the polymer region, the first surface joined to the substrate, has a greater total thickness variation than a second surface of the polymer region, the second surface joined to the component.

Example 31 provides a substrate including a first layer including a dielectric material, the first layer having a first width; a second layer including the dielectric material, the second layer over the first layer; a polymer region within the second layer, the polymer region having a second width that is less than the first width; and a component over the polymer region, the component having a third width that is less than the second width.

Example 32 provides the substrate of example 31, where the polymer region extends between a side of the component to the first layer of the substrate.

Example 33 provides the substrate of example 31 or 32, where the second layer includes a cavity, and the component and the polymer region are within the cavity of the substrate.

Example 34 provides the substrate of any of examples 31-33, where the polymer region is a first polymer region, the substrate further including a second polymer region within the second layer, the second polymer region having a greater height than the first polymer region; and a second component over the second polymer region.

Example 35 provides the substrate of any of examples 31-34, where the polymer region includes polyurethane.

Example 36 provides the substrate of any of examples 31-34, where the polymer region includes polyimide.

Example 37 provides the substrate of any of examples 31-34, where the polymer region includes at least one of polyvinyl acetate, epoxy, and acrylic.

Example 38 provides the substrate of any of examples 31-37, where the polymer region has a coefficient of thermal expansion (CTE) of less than 10 parts per million per degree Celsius (ppm/° C.).

Example 39 provides the substrate of any of examples 31-38, further including a dielectric region between the component and the dielectric material of the second layer, the dielectric region including a dielectric material different from the polymer region.

Example 40 provides the substrate of example 39, where the dielectric region is a first dielectric region, the substrate further including a second dielectric region between the component and the dielectric material of the second layer, the second dielectric region on an opposite side of the component from the first dielectric region.

Example 41 provides the substrate of any of examples 31-38, where the polymer region is a first polymer region, the substrate further including a second polymer region between the component and the dielectric material of the second layer, the second polymer region over the first polymer region.

Example 42 provides the substrate of example 41, where the second polymer region includes a polymer material different from a polymer material of the first polymer region.

Example 43 provides the substrate of example 41, where the first polymer region and the second polymer region include a same polymer material.

Example 44 provides the substrate of any of examples 41-43, further including a third polymer region between the component and the dielectric material of the second layer and over the first polymer region, the third polymer region on an opposite side of the component from the second polymer region.

Example 45 provides the substrate of any of examples 41-44, where the second polymer region has a coefficient of thermal expansion (CTE) of less than 10 parts per million per degree Celsius (ppm/° C.).

Example 46 provides the substrate of any of examples 31-45, the polymer region having a first surface between the polymer region and the first layer and a second surface between the polymer region and the component, the first surface parallel to the second surface.

Example 47 provides the substrate of example 46, where the first surface has a first total thickness variation (TTV), the second surface has a second TTV, and the first TTV is greater than the second TTV.

Example 48 provides a method including forming a cavity in a substrate, the cavity having a depth less than a thickness of the substrate; depositing a polymer material along a base of the cavity; curing the polymer material; and placing a component in the cavity and over the cured polymer material, the component including a passive device.

Example 49 provides the method of example 48, where the polymer material has a coefficient of thermal expansion (CTE) of less than 10 parts per million per degree Celsius (ppm/° C.).

Example 50 provides the method of example 48 or 49, where the polymer material is a self-leveling polymer material.

Example 51 provides the method of any of examples 48-50, where the base of the cavity has a first total thickness variation (TTV), an upper surface of the cured polymer material has a second total thickness variation (TTV), and the first TTV is greater than the second TTV.

Example 52 provides a method including forming a cavity in a substrate; measuring a depth of the cavity, the depth of the cavity less than a height of the substrate; providing a polymer region along a base of the cavity, a height of the of polymer region based on the measured depth of the cavity; and placing a component in the cavity and over the polymer region, the component including a passive device.

Example 53 provides the method of example 52, further including measuring a width of the cavity, where an amount of material deposited for the polymer region is based on the depth of the cavity and the width of the cavity.

Example 54 provides the method of example 52 or 53, further including measuring a position of the component in the cavity; removing the component from the cavity; providing an additional polymer layer over the polymer region; and placing the component in the cavity and over the additional polymer layer.

Example 55 provides the method of any of examples 52-54, where the polymer region includes a die attach film.

Example 56 provides a method including forming a cavity in a substrate, the cavity having a depth less than a thickness of the substrate; depositing a polymer layer along a base of the cavity; placing a component in the cavity and over the polymer layer; and depositing a polymer material in the cavity and over the polymer layer, the polymer material abutting the component.

Example 57 provides the method of example 56, where a first region of the polymer material is between a first side of the component and a first cavity wall, and a second region of the polymer material is between a second side of the component and a second cavity wall, the second side of the component opposite the first side.

Example 58 provides the method of example 56 or 57, further including curing the polymer layer and the polymer material.

Example 59 provides the method of any of examples 56-58, where the polymer layer includes the polymer material.

Example 60 provides the method of any of examples 56-58, where the polymer material is a first polymer material, and the polymer layer includes a second polymer material different from the first polymer material.

Example 61 provides an assembly including a substrate having a cavity formed therein, the cavity having a base, a first sidewall, and a second sidewall opposite the first sidewall; a component at least partially in the cavity; and a polymer region within the cavity, the polymer region including a first portion between the component and the base of the cavity and a second portion between the component and the first sidewall.

Example 62 provides the assembly of example 61, where the cavity has a first height, and the polymer region has a second height less than the first height.

Example 63 provides the assembly of example 62, further including a dielectric region over the second portion of the polymer region, the dielectric region between the sidewall of the substrate and the component.

Example 64 provides the assembly of example 61, where the cavity has a first height, and the polymer region has a second height equal to the first height.

Example 65 provides the assembly of any of examples 61-64, where an upper side of the component is a greater distance from the base of the cavity than an upper side of the substrate.

Example 66 provides the assembly of any of examples 61-64, where an upper side of the component is coplanar with an upper side of the substrate.

Example 67 provides the assembly of any of examples 61-66, the polymer region further including a third portion between the component and the second sidewall.

Example 68 provides the assembly of any of examples 61-67, where the polymer region encases at least a lower portion of the component.

Example 69 provides the assembly of any of examples 61-68, the first portion of the polymer region having a first surface along the base of the substrate and a second surface along a base of the component.

Example 70 provides the substrate of example 69, where the first surface has a first total thickness variation (TTV), the second surface has a second TTV, and the first TTV is greater than the second TTV.

Example 71 provides a method including forming a cavity in a substrate, the cavity having a depth less than a thickness of the substrate; depositing a polymer material in a cavity; placing a component in the cavity such that a portion of the polymer material is displaced by a portion of the component; and curing the polymer material.

Example 72 provides the method of example 71, further including adhering a first side of the component to a carrier structure; and inserting the component into the cavity while the component is attached to the carrier structure.

Example 73 provides the method of example 72, where the component has a second side opposite the first side, and the second side is pressed into the polymer material.

Example 74 provides the method of example 72 or 73, further including removing the carrier structure from the component after inserting the component into the cavity.

Example 75 provides the method of any of examples 71-74, further including depositing a dielectric material over the cured polymer material, the dielectric material between a sidewall of the cavity and a side of the component.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An assembly comprising:
a substrate having a first side and a second side opposite the first side;
a component at least partially embedded in the substrate, the component having a first side and a second side opposite the first side, wherein the first side of the component is above the first side of the substrate; and
a metal pad in the substrate, the metal pad between the first side of the substrate and the first side of the component.

2. The assembly of claim 1, wherein the component comprises a passive device.

3. The assembly of claim 2, wherein the passive device is a capacitor.

4. The assembly of claim 1, wherein the metal pad comprises copper.

5. The assembly of claim 1, wherein the metal pad has a thickness of less than 50 microns.

6. The assembly of claim 1, wherein the first side of the component has a first surface area, and a side of the metal pad has a second surface area that is greater than the first surface area.

7. The assembly of claim 1, wherein the metal pad is fully embedded in the substrate.

8. The assembly of claim 1, wherein the substrate comprises a plurality of dielectric layers, wherein at least a first dielectric layer is between the first side of the substrate and the first side of the component.

9. The assembly of claim 8, wherein a second dielectric layer of the plurality of dielectric layers is in a same layer as the component.

10. The assembly of claim 1, wherein the metal pad is electrically isolated from the component.

11. An assembly comprising:
a substrate having a first side and a second side opposite the first side;
a component at least partially embedded in the substrate, the component having a first side between the first side of the substrate and the second side of the substrate; and
a polymer region embedded in the substrate, the polymer region between the first side of the substrate and the first side of the component.

12. The assembly of claim 11, wherein the polymer region is joined to the first side of the component.

13. The assembly of claim 11, wherein the component is within a cavity of the substrate, the cavity having a greater width than the component.

14. The assembly of claim 13, wherein the polymer region extends across a base of the cavity, the polymer region has a greater width than the component, and the polymer region has a same width as the cavity.

15. The assembly of claim 11, wherein the component comprises a passive device.

16. The assembly of claim 11, wherein the substrate comprises a plurality of dielectric layers, wherein at least a first dielectric layer is between the first side of the substrate and the polymer region.

17. The assembly of claim 11, wherein a first surface of the polymer region, the first surface joined to the substrate, has a greater total thickness variation than a second surface of the polymer region, the second surface joined to the component.

18. A substrate comprising:
a first layer comprising a dielectric material, the first layer having a first width;
a second layer comprising the dielectric material, the second layer over the first layer;
a polymer region within the second layer, the polymer region having a second width that is less than the first width; and
a component over the polymer region, the component having a third width that is less than the second width.

19. The substrate of claim 18, wherein the polymer region extends between a side of the component to the first layer of the substrate.

20. The substrate of claim 18, wherein the polymer region is a first polymer region, the substrate further comprising:
a second polymer region within the second layer, the second polymer region having a greater height than the first polymer region; and
a second component over the second polymer region.
